(19) United States
(12) Patent Application Publication
(10) Pub. No.: US 2006/0137611 A1
(43) Pub. Date: Jun. 29, 2006

(54) Plasma apparatus

(75) Inventors: Hee-Hwan Choe, Incheon City (KR); Sang-Gab Kim, Seoul (KR); Min-Seok Oh, Yongin-si (KR); Hong-Kee Chin, Suwon-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/298,107

(22) Filed: Dec. 9, 2005

(30) Foreign Application Priority Data
Dec. 24, 2004 (KR) 2004-112123

(51) Int. Cl. C23C 16/00; C23F 1/00

(52) U.S. Cl. 118/723 I; 156/345.48

(57) ABSTRACT

The present invention relates to a plasma apparatus comprising a reaction chamber having a reaction space which accommodates a substrate to be treated; a coil located on the outside of the reaction space; a power source applying alternating frequency power on the coil; and a conducting plate located between the coil and the reaction space and generating an induced current from the alternating frequency power applied on the coil. Thus, the present invention provides a plasma apparatus that induces a uniform electric field in an internal gas of the reaction chamber.

### CROSS-REFERENCE TO RELATED APPLICATIONS

This application claims priority under 35 U.S.C. §119 to Korean Patent Application No. 2004-0112123, filed on Dec. 24, 2004, the disclosure of which is incorporated herein by reference.

### BACKGROUND OF THE INVENTION

1. Field of the Invention

The present invention relates to a plasma apparatus, and more particularly, to an inductively coupled plasma (ICP) apparatus.

2. Description of the Related Art

Generally, a plasma apparatus is used for etching, depositing or stripping certain materials on the surfaces of wafers to fabricate semiconductor devices, or on substrates to fabricate liquid crystal display (LCD) panels.

The plasma apparatus requires that the plasma generated therein maintain a high uniformity as well as a high density.

Various methods may be used to form plasma including, but not limited to, a capacitive coupled plasma (CCP) method and an inductively coupled plasma (ICP) method. The ICP method may generate plasma with a high density and high uniformity.

An ICP type plasma apparatus comprises a reaction chamber including a reaction space for generating plasma, a coil and a power source disposed on the outside of the reaction chamber, and a dielectric plate between the reaction chamber and the coil. Generally, the dielectric plate comprises a quartz or ceramic material.

If high frequency power is applied on the coil through a power source, an electric field will be induced on the internal gas of the reaction space through the dielectric plate.

However, if the plasma process has been progressing for many hours, the polymer that has been accumulated as a byproduct during the plasma process will deposit on the surface of the dielectric plate facing the reaction space where the dielectric plate corresponds to the coil. The polymer may fall on the substrate inside of the reaction chamber to thereby cause a defect. Also, the surface of the dielectric plate corresponding to the coil will be etched. Thus, the dielectric plate may have a short life, and so will require frequent replacement.

Basically, these problems stem from irregularity of the electric field that is applied to the internal gas of the reaction chamber through the dielectric plate.

### SUMMARY OF THE INVENTION

Accordingly, it is an aspect of the present invention to provide a plasma apparatus that applies a uniform electric field upon an internal gas of the reaction chamber.

A plasma apparatus is provided, comprising: a reaction chamber having a reaction space to accommodate a substrate to be treated, a coil located on the outside of the reaction space, a power source applying alternating frequency power on the coil, and a conducting plate located between the coil and the reaction space and generating an induced current from the alternating frequency power applied on the coil.

According to another aspect of the invention, the high frequency power is below about 1 MHz.

According to another aspect of the invention, the high frequency power is below about 500 KHz.

According to another aspect of the invention, the conducting plate covers a substantial portion of the upper part of the reaction space.

According to another aspect of the invention, further comprising an insulating part located between the reaction space and the conducting plate.

According to another aspect of the invention, the insulating part comprises a ceramic material.

According to another aspect of the invention, the size of the conducting plate is larger than about 1 m×1 m.

According to another aspect of the invention, the thickness of the conducting plate is below about 3 cm.

According to another aspect of the invention, the conducting plate is formed by a metal that comprises at least one of aluminum, iron, copper, silver, and nickel.

According to another aspect of the invention, further comprising a lower electrode located in the reaction space and having a shape of a plate, and a lower power applying the high frequency power on the lower electrode.

According to another aspect of the invention, the lower electrode is disposed parallel to the conducting plate.

According to another aspect of the invention, the substrate is seated on the lower electrode.

According to another aspect of the invention, the substrate is used to fabricate a liquid crystal display.

According to another aspect of the invention, the coil covers a substantial portion of the conducting plate.

According to another aspect of the present invention, a plasma apparatus comprises: a reaction chamber having a reaction space to accommodate a substrate to be treated, a coil located on the outside and in an upper part of the reaction space over the area thereof, a power source applying alternating frequency power on the coil, conducting plate located between the coil and the reaction space and which generates an induced current from the alternating frequency power applied on the coil, a gas inlet to allow an inlet gas to flow into the reaction space, and a gas outlet to allow an outlet gas to flow out of the reaction space.

According to another aspect of the invention, the gas inlet allows a source gas to flow into the reaction space, and the gas outlet allows a reacted source gas and a by-product from an etching process to flow out of the reaction space.

According to another aspect of the invention, further comprising a supporting member attached to the conducting plate to maintain the height level of the conducting plate.

### BRIEF DESCRIPTION OF THE DRAWINGS

These and other aspects of the present invention will become apparent and more readily appreciated from the following description of the embodiments, taken in conjunction with the accompanying drawings of which:

FIG. 1 is a perspective view of a plasma apparatus according to a first embodiment of the present invention;

FIG. 2 is a sectional view of the plasma apparatus according to the first embodiment of the present invention;

FIG. 3 is a view explaining an induced current that is formed with a conducting plate according to an embodiment of the present invention;

FIG. 4 is a view explaining an intensity change of the induced current according to a thickness of the conductive plate according to an embodiment of the present invention;

FIG. 5 is a perspective view of a plasma apparatus according to a second embodiment of the present invention; and

FIG. 6 is an expanded sectional view of the part A in FIG. 5.

### DETAILED DESCRIPTION OF THE PREFERRED EMBODIMENTS

Reference will now be made in detail to the embodiments of the present invention, examples of which are illustrated in the accompanying drawings, wherein like reference numerals refer to like elements throughout. The embodiments are described below to explain the present invention by referring to the figures.

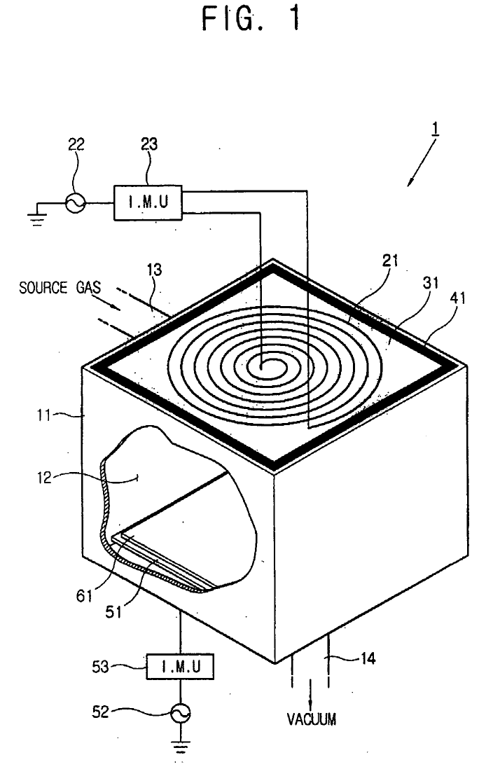

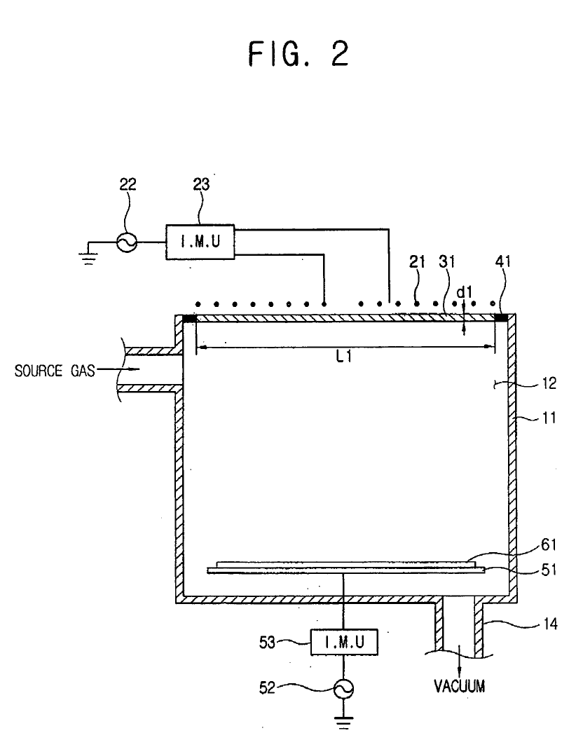

FIGS. 1 and 2 schematically show a plasma apparatus according to a first embodiment of the present invention.

As shown in FIGS. 1 and 2, a plasma apparatus 1 comprises a reaction chamber 11, a coil 21, and a conducting plate 31.

The reaction chamber 11 is approximately a rectangular parallelepiped form and comprises a reaction space 12 for generating plasma. On an upper part of the reaction chamber 11 is formed an inlet 13 to flow in a source gas. If the use of the source gas is for etching, the source gas comprises at least one of sulfur fluoride (SF₆), chlorine (Cl₂), hydrochloric acid (HCl), carbon fluoride (CF₄), oxygen, nitrogen, helium, and argon. Also, if the use of the source gas is for depositing, the source gas comprises at least one of silane (SiH₄), methane (CH₄), ammonium (NH₃), and nitrogen.

In another embodiment of the present invention, the inlet 13 may be provided in the upper part of the reaction space 12, i.e., in the conducting plate 31. Also, the inlet 13 may be provided in a plurality of conduits to provide the reaction space 12 with the source gas uniformly. On the lower part of the reaction chamber 11 is formed an outlet 14 to allow the reacted source gas and the by-product from the etching process to flow out of the reaction space 12. The position and the number of the outlet 14 may be changed as needed. The outlet 14 is preferably, but not necessarily, connected to a pump (not shown).

The pump makes the reacted source gas and the by-product flow out to the outside of the reaction space 12 effectively and maintains the vacuum level of the reaction space 12 efficiently.

The coil 21 is located outside of the reaction space 12. The coil 21 is located in the upper part of the reaction space 12 over the area thereof. The coil 21 is connected to a power source 22 that applies high frequency power (or RF power). An impedance matching unit 23 is provided between the coil 21 and the power source 22.

The conducting plate 31 is disposed between the reaction space 12 and the coil 21. That is, the conducting plate 31 separates the reaction space 12 and the coil 21. The coil 21 is provided at predetermined intervals that are parallel to the conducting plate 31. The conducting plate 31 is formed by a metal plate that comprises at least one of aluminum, iron, copper, silver, and nickel. The conducting plate 31 is rectangular. The thickness of the conducting plate 31 is preferably but not necessarily less than about 3 cm. If the thickness of the conducting plate 31 is over about 3 cm, the induced current that is formed with the conducting plate 31 will not generate on the reaction space 12 sufficiently. The particular description of the conducting plate 31 will be described later. The length and width of the conducting plate 31 are each preferably equal to or larger than about 1 m, because the size of the substrate 61 that is to be treated increases.

An insulating part 41 is provided between the reaction chamber 11 and the conducting plate 31. The insulating part 41 is shaped like a quadrangular band and comprises an insulating material like ceramics. The insulating part 41 electrically separates the reaction chamber 11 and the conducting plate 31. The conducting plate 31 is floating or held in suspension because it is not connected with the coil 21. The distance of the connection between the conducting plate 31 and the insulating part 41 as well as the connection of the reaction chamber 11 to the insulating part 41 may close up to maintain a predetermined vacuum level.

On the lower part of the reaction space 12 is provided a lower electrode 51. The lower electrode 51 is shaped like a plate and disposed substantially in parallel to the conducting plate 31. Also, the lower electrode 51 may be made of aluminum. The lower electrode 51 is preferably but not necessarily larger than the substrate 61 that is the object of treatment because the substrate 61 is seated thereon. The lower electrode 51 is connected with a lower power source 52 that applies alternating frequency power, and a lower impedance matching unit 53 is provided between the lower electrode 51 and the lower power source 52. If high frequency power is applied on the lower electrode 51, the plasma in the reaction space 12 will be more uniformed.

The substrate 61 that is the object of treatment is seated on the lower electrode 51. The substrate 61 may be a wafer for fabricating a semiconductor device, or a thin film transistor substrate or a color filter substrate for fabricating a liquid crystal display. According to an embodiment of the present invention, a larger reaction space 12 may correspond to greater uniformity. Further, the larger reaction space 12 having greater uniformity in the plasma facilitates processing a larger substrate 61 for fabricating a liquid crystal display.

The principle of inducing an electric field on the reaction space 12 will be described as follows in the plasma apparatus 1 according to the first embodiment.

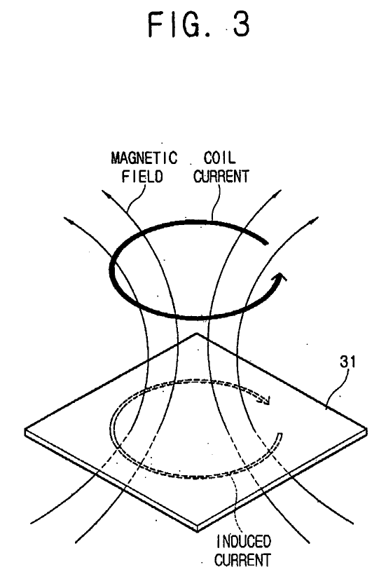

Referring to FIG. 3, if the power source 22 applies high frequency power on the coil 21, a current flows in the coil 21. For example, current will flow in a counterclockwise direction as shown in FIG. 2. Also, the current of the coil 21 makes a magnetic field that pass through the conducting plate 31. At this point, the conducting plate 31 forms an induced current that flows in a clockwise direction. The induced current flows in a direction exactly against the current of the coil 21.

A cause of forming an induced current will be described as follow. If alternating current flowing to the coil 21 is near a conductor, a magnetic field that is generated to the surroundings of the coil 21 acts on the conductor. At this point, the conductor has electromotive force that interrupts a change in the magnetic flux passing through it.

This phenomenon is electromagnetic induction. The current that is formed with electromotive force is an induced current or an eddy current.

Hence, the electric field of the induced current that is generated to the coil 21 is generated on the reaction space 12 to generate plasma.

The conducting plate 31 according to an embodiment of the present invention generally forms a uniform electric potential. Therefore, the polymer will not deposit onto the surface of the conducting plate 31 locally. Also, the surface of the conducting plate 31 will not etch. Moreover, because the density of the plasma that exists in the inside of the reaction space 12 is uniform, the substrate 61 may be easily treated.

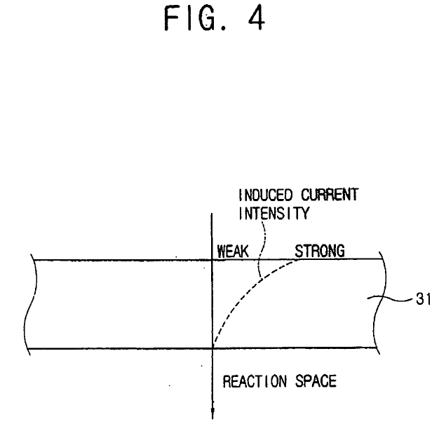

The conducting plate 31 that forms the fitting density of the plasma will be described below with reference to FIG. 4.

The strength of an induced current can weaken due to the thickness of the conducting plate 31. As a result, the induced current is strongest at a position adjacent to the coil 21, and the induced current weakens at a position closer to the reaction space 12.

The formula of the skip depth (δ) that the induced current diminishes at a rate of 1/e (where e=2.718) is described as follow.
δ∝(2/ωμσ)^{1/2}

ω is angular frequency, that is, 2πf (f is a frequency of an alternating frequency power). μ is the magnetic permeability of the conducting plate 31. σ is the electric conductivity of the conducting plate 31.

Accordingly, if the frequency of the alternating frequency power decreases or the conducting plate 31 is formed with material of significant magnetic permeability and electric conductivity, the skip depth (δ) will increase. Therefore, the frequency of an alternating frequency power has a significant effect upon the skip depth (δ). Generally, the frequency of the alternating frequency power to form plasma is about 13.56 MHz. On the other hand, the frequency of the alternating frequency power according to a first embodiment of the present invention is below about 1 MHz, and preferably below about 500 KHz.

Another method to increase the strength of an electric field generated on the reaction space 12 is to use a thinner conducting plate 31. Accordingly, the thickness of the conducting plate 31 is preferably less than about 3 cm.

Preferably, the thickness and material of the conducting plate 31 is determined in consideration with the intensity of an induced current as well as the size and shape of the conducting plate 31.

The plasma apparatus 1 according to the first embodiment of the present invention may be changed in accordance to different reaction conditions. For instance, the shape of the reaction chamber 11 is not limited to a hexahedron, but may be provided as a cylinder. At this point, the coil 21, the conducting plate 31 and the insulating part 41 will be changed according to the shape of the reaction chamber 11.

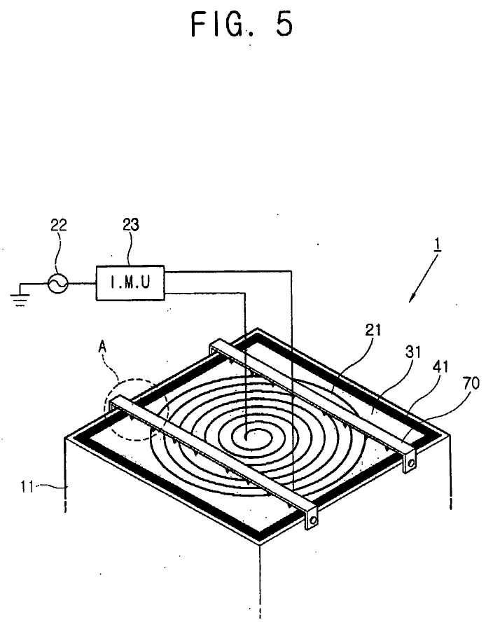

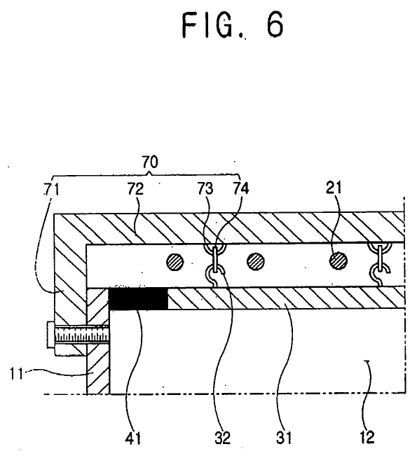

The plasma apparatus 1 according to a second embodiment of the present invention will be described below with reference to FIGS. 5 and 6. Reference numerals identical to those of a first embodiment of the present invention denote identical elements, and detailed description of these identical elements will not be repeated.

FIG. 5 is a perspective view of a plasma apparatus according to a second embodiment of the present invention, and FIG. 6 is an expanded sectional view of the part A in FIG. 5.

The plasma apparatus 1 according to the second embodiment of the present invention further comprises a couple of support members 70 that are parallel to each other and support the conducting plate 31 at the upper part of the coil 21.

The support member 70 comprises a pair of fixing parts 71, and a supporting bar 72 connecting the pair of fixing parts 71 to each other. The fixing parts 71 are fixed by a screw at a side wall of the reaction chamber 11. The supporting bar 72 traverses the conducting plate 31. Also, it is preferable but not necessary that the fixing parts 71 and the supporting bar 72 are integrally formed with a strong metal.

The surface of the supporting bar 72 facing the conducting plate 31 has ring fixing parts 73 at regular intervals. Each ring fixing part 73 is projected and connected with a ring 74.

The conducting plate 31 comprises a link 32 to be aligned with the ring fixing part 73. The link 32 may be fixed by welding at the conducting plate 31.

The support member 70 supports the conducting plate 31 because the ring 74 of the support member 70 connects with the ring fixing part 73 and the link 32 respectively.

If the substrate 61 to be treated is of a larger size, the conducting plate 31 may also be larger. The edge of the conducting plate 31 is supported by the insulating part 41 fixed on the reaction chamber 11. However, the center portion of the conducting plate 31 is not supported. Therefore, the conducting plate 31 may be bent to the reaction space 12.

Particularly, to maintain the intensity of a fitting induced current, the thickness of the conducting plate 31 should remain thin. Further, the bending of the conducting plate 31 may be severe because the reaction space 12 is applied to a vacuum.

Thus, it is preferred that the support member 70 according to the second embodiment of the present invention maintains the height level of the conducting plate 31.

The support member 70 is disposed at the upper part of the coil 21, so that the distance between the coil 21 and the conducting plate 31 is not increased. Therefore, the intensity of an induced current formed by the conducting plate 31 is not substantially changed.

The plasma apparatus 1 according to the second embodiment of the present invention may be changed in accordance to different reaction conditions. For instance, the number of the support member 70 and the establishment direction of the support member 70 may be changed as necessary. Also, it is possible that the supporting bar 72 connect with each other or the support member 70 further comprises an extra structure supporting the middle of the supporting bar 72, thereby preventing the support member 70 from bending.

Although a few embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. A plasma apparatus comprising:
a reaction chamber having a reaction space to accommodate a substrate to be treated;
a coil located on the outside of the reaction space;
a power source applying alternating frequency power on the coil; and
a conducting plate located between the coil and the reaction space and generating an induced current from the alternating frequency power applied on the coil.

2. The plasma apparatus according to claim 1, wherein the high frequency power is below about 1 MHz.

3. The plasma apparatus according to claim 2, wherein the high frequency power is below about 500 KHz.

4. The plasma apparatus according to claim 1, wherein the conducting plate covers a substantial portion of the upper part of the reaction space.

5. The plasma apparatus according to claim 1, further comprising an insulating part located between the reaction space and the conducting plate.

6. The plasma apparatus according to claim 5, wherein the insulating part comprises ceramic material.

7. The plasma apparatus according to claim 1, wherein the size of the conducting plate is larger than about 1 m×1 m.

8. The plasma apparatus according to claim 1, wherein the thickness of the conducting plate is less than about 3 cm.

9. The plasma apparatus according to claim 1, wherein the conducting plate is formed by a metal that comprises at least one of aluminum, iron, copper, silver, and nickel.

10. The plasma apparatus according to claim 1, further comprising a lower electrode located in the reaction space and having a shape of a plate, and a lower power applying the high frequency power on the lower electrode.

11. The plasma apparatus according to claim 10, the lower electrode is disposed parallel to the conducting plate.

12. The plasma apparatus according to claim 10, wherein the substrate is seated on the lower electrode.

13. The plasma apparatus according to claim 1, wherein the substrate is used to fabricate a liquid crystal display.

14. The plasma apparatus according to claim 1, wherein the coil covers a substantial portion of the conducting plate.

15. A plasma apparatus comprising:
a reaction chamber having a reaction space to accommodate a substrate to be treated;
a coil located on the outside and in the upper part of the reaction space over the area thereof;
a power source applying alternating frequency power on the coil; and
a conducting plate located between the coil and the reaction space and which generates an induced current from the alternating frequency power applied on the coil;
a gas inlet to allow an inlet gas to flow into the reaction space; and
a gas outlet to allow an outlet gas to flow out of the reaction space.

16. The plasma apparatus according to claim 15, wherein the coil is located above a substantial portion of the conducting plate.

17. The plasma apparatus according to claim 15, wherein the gas inlet allows a source gas to flow into the reaction space, and the gas outlet allows a reacted source gas and a by-product from an etching process to flow out of the reaction space.

18. The plasma apparatus according to claim 15, further comprising an insulating part located between the reaction space and the conducting plate.

19. The plasma apparatus according to claim 15, further comprising a lower electrode located in the reaction space and having a shape of a plate, and a lower power applying the alternating frequency power on the lower electrode.

20. The plasma apparatus according to claim 15, further comprising a supporting member attached to the conducting plate to maintain the height level of the conducting plate.
